(19) United States
(12) Patent Application Publication
(10) Pub. No.: US 2024/0079404 A1
(43) Pub. Date: Mar. 7, 2024

(54) ELECTROSTATIC PROTECTION STRUCTURE AND PREPARATION METHOD THEREFOR

(71) Applicant: CSMC TECHNOLOGIES FAB2 CO., LTD., Wuxi (CN)

(72) Inventor: Jun SUN, Wuxi (CN)

(21) Appl. No.: 18/262,100

(22) PCT Filed: Jan. 21, 2022
(86) PCT No.: PCT/CN2022/073080

§ 371 Date: Jul. 19, 2023

(30) Foreign Application Priority Data
Jun. 15, 2021 (CN) 202110658518.4

(51) Int. Cl. H01L 27/02

(52) U.S. Cl. CPC H01L 27/0259

(57) ABSTRACT

The present application relates to an electrostatic protection structure and a preparation method therefor. The electrostatic protection structure comprises a substrate, a buried layer, a first deep well, a second deep well and a third deep well. A well region of the opposite conductivity type and a heavily doped region of the same conductivity type are provided in the first deep well, and well regions and heavily doped regions of the same conductivity type are respectively provided in the second deep well and the third deep well. The first deep well, a first well region and a second well region are floating; a first heavily doped region leads out electrostatic voltage; and a sixth heavily doped region is grounded.

### CROSS REFERENCE TO RELATED APPLICATION

The present application claims priority to Chinese Patent Application with No. 202110658518.4, entitled “Electrostatic Protection Structure and Preparation Method Therefor”, and filed on Jun. 15, 2021, the content of which is expressly incorporated herein by reference in its entirety.

### TECHNICAL FIELD

The present disclosure relates to the field of semiconductor technology, and particularly to an electrostatic protection structure and a manufacture method thereof.

### BACKGROUND

The description herein merely provides background information related to the present disclosure and does not definitely constitute exemplary techniques.

As the high-voltage devices are more and more widely used in the integrated circuits, the requirement for the Electrostatic Discharge (ESD) capability is also becoming higher and higher. The high-voltage electrostatic protection structure is usually a structure composed of multiple low-voltage devices connected in series to meet the requirement of high-voltage resistance.

However, the conventional high-voltage electrostatic protection structure usually has no problem with the forward voltage withstand, but cannot withstand the high voltage in a reverse direction, accordingly there exists a problem that the forward ESD protection capability is inconsistent with the reverse ESD protection capability.

### SUMMARY

According to various embodiments of the present disclosure, an electrostatic protection structure and a manufacture method thereof are provided.

An electrostatic protection structure includes:
a substrate, having a first conductivity type;
a buried layer, located in the substrate and having a second conductivity type opposite to the first conductivity type;
a first deep well, located on an upper surface of the buried layer and floating, and having the first conductivity type;
a second deep well, located on the upper surface of the buried layer, a partial region of the second deep well being in contact with the substrate, having the second conductivity type, the second deep well being adjacent to the first deep well and being located at a periphery of the first deep well; and
a third deep well, located in the buried layer and completely in contact with the substrate, having the first conductivity type, the third deep well being adjacent to the second deep well and being located at a periphery of the second deep well.

An upper surface layer of the first deep well is provided with a first well region and a second well region which are isolated from each other and are floating, both the first well region and the second well region have the second conductivity type, an upper surface layer of the first well region is provided with a first heavily doped region and a second heavily doped region isolated from each other, an upper surface layer of the second well region is provided with a third heavily doped region and a fourth heavily doped region isolated from each other. The first heavily doped region, the second heavily doped region, the third heavily doped region and the fourth heavily doped region have the first conductivity type. The first heavily doped region is led out as a first electrode and is connected to an electrostatic port; the second heavily doped region is led out as a second electrode. The third heavily doped region is led out as a third electrode and is electrically connected to the second electrode; the fourth heavily doped region is led out as a fourth electrode;

An upper surface layer of the second deep well is provided with a third well region, the third well region has the second conductivity type, and an upper surface layer of the third well region is provided with a floating fifth heavily doped region having the second conductivity type.

An upper surface layer of the third deep well is provided with a fourth well region, the fourth well region has the first conductivity type, an upper surface layer of the fourth well region is provided with a sixth heavily doped region, the sixth heavily doped region has the first conductivity type, and the sixth heavily doped region is led out and is grounded together with the fourth electrode.

In an embodiment, the first conductivity type is a P-type, and the second conductivity type is a N-type. When the electrostatic port inputs an electrostatic voltage:
the first heavily doped region, the first well region and the second heavily doped region together form a first PNP transistor; the third heavily doped region, the second well region and the fourth heavily doped region together form a second PNP transistor; and the first PNP transistor is connected to the second PNP transistor in series.

In an embodiment, when the electrostatic voltage is a positive voltage:
the first electrode serves as an emitter of the first PNP transistor, the second electrode serves as a collector of the first PNP transistor, and the first well region serves as a base of the first PNP transistor; and
the third electrode serves as an emitter of the second PNP transistor, the fourth electrode serves as a collector of the second PNP transistor, and the second well region serves as a base of the second PNP transistor.

In an embodiment, when the electrostatic voltage is a negative voltage:
the first electrode serves as a collector of the first PNP transistor, the second electrode serves as an emitter of the first PNP transistor, and the first well region serves as a base of the first PNP transistor; and
the third electrode is a collector of the second PNP transistor, the fourth electrode is an emitter of the second PNP transistor, and the second well region serves as a base of the second PNP transistor.

In an embodiment, there exists at least two first heavily doped regions, at least two second heavily doped regions, at least two third heavily doped regions, and at least two fourth heavily doped regions.

A plurality of the first heavily doped regions are isolated from each other, a plurality of the second heavily doped regions are isolated from each other, a plurality of the third heavily doped regions are isolated from each other, and a plurality of the fourth heavily doped regions are isolated from each other.

In an embodiment, the plurality of the first heavily doped regions are electrically connected to each other as the first electrode, the plurality of the second heavily doped regions are electrically connected to each other as the second electrode, the plurality of the third heavily doped regions are electrically connected to each other as the third electrode, and the plurality of the fourth heavily doped regions are electrically connected to each other as the fourth electrode.

In an embodiment, at least one fifth well region is provided between the first well region and the second well region in the upper surface layer of the first deep well, the fifth well region is respectively isolated from the first well region and the second well region, and the fifth well region has the second conductivity type.

An upper surface layer of each fifth well region is provided with a seventh heavily doped region and an eighth heavily doped region of the first conductivity type, the seventh heavily doped region of each fifth well region is electrically connected to an eighth heavily doped region of an adjacent fifth well region, the seventh heavily doped region adjacent to the first well region is electrically connected to the second heavily doped region, and the eighth heavily doped region adjacent to the second well region is electrically connected to the third heavily doped region.

In an embodiment, the upper surface layer of the first deep well is further provided with a plurality of sixth well regions, the plurality of sixth well regions are arranged alternatively with the first well region and the second well region, and the sixth well regions have the first conductivity type.

In embodiment, the second deep well is a circular structure and surrounds the periphery of the first deep well, the third deep well is a circular structure and surrounds the periphery of the second deep well.

A manufacture method for an electrostatic protection structure includes:
providing a substrate having a first conductivity type;
forming a buried layer in the substrate the buried layer having a second conductivity type opposite to the first conductivity type;
   forming a first deep well on an upper surface of the buried layer, the first deep well being floating and having the first conductivity type;
forming a second deep well on the upper surface of the buried layer, a partial region the second deep well being in contact with the substrate and having the second conductivity type, the second deep well being adjacent to the first deep well and being located at a periphery of the first deep well;
forming a third deep well in the buried layer, the third deep well being completely in contact with the substrate and having the first conductivity type, the third deep well being adjacent to the second deep well and being located at a periphery of the second deep well;
forming a first well region and a second well region isolated from each other and floating in the upper surface layer of the first deep well, both the first well region and the second well region having the second conductivity type; forming a first heavily doped region and a second heavily doped region isolated from each other in the upper surface layer of the first well region; forming a third heavily doped region and a fourth heavily doped region isolated from each other in the upper surface layer of the second well region, the first heavily doped region, the second heavily doped region, the third heavily doped region and the fourth heavily doped region having the first conductivity type, the first heavily doped region being led out as a first electrode and is connected to an electrostatic port, the second heavily doped region being led out as a second electrode, the third heavily doped region being led out as a third electrode and being electrically connected to the second electrode, and the fourth heavily doped region being led out as a fourth electrode;
forming a third well region in the upper surface layer of the second deep well, the third well region having the second conductivity type; forming a floating fifth heavily doped region in the upper surface layer of the third well region, the fifth heavily doped region having the second conductivity type;
forming a fourth well region in the upper surface layer of the third deep well, the fourth well region having the first conductivity type; and forming a sixth heavily doped region in an upper surface layer of the fourth well region, the sixth heavily doped region having the first conductivity type, and the sixth heavily doped region being led out and being grounded together with the fourth electrode.

The details of one or more embodiments of the present disclosure are set forth in the accompanying drawings and the description below. Other features, purposes and advantages of the present disclosure will be obvious from the specification, drawings and claims.

### BRIEF DESCRIPTION OF THE DRAWINGS

In order to more clearly describe the technical solution in the embodiments or exemplary techniques of the present disclosure, accompanying drawings that need to be used in the description of the embodiments or exemplary techniques will be briefly introduced. Obviously, the accompanying drawings in the following description are merely some embodiments of the present disclosure. Those of ordinary skill in the art can obtain drawings of other embodiments based on these drawings without creative work.

FIG. 1 is a schematic cross-sectional structure diagram of an electrostatic protection structure according to an embodiment.

FIG. 2 is a schematic cross-sectional structure diagram of an electrostatic protection structure according to an embodiment.

FIG. 3 is a schematic cross-sectional structure diagram of an electrostatic protection structure according to an embodiment.

FIG. 4 is a schematic cross-sectional structure diagram of an electrostatic protection structure according to an embodiment.

FIG. 5 is an equivalent schematic diagram of an electrostatic protection structure according to an embodiment.

FIG. 6 is a schematic cross-sectional structure diagram of an electrostatic protection structure according to an embodiment.

FIG. 7 is a flow chart showing a manufacture method for an electrostatic protection structure according to an embodiment.

FIG. 8 is a flow chart showing a manufacture method for an electrostatic protection structure according to an embodiment.

### DETAILED DESCRIPTION

In order to facilitate the understanding of the present disclosure, the present disclosure will be detailed more fully below with reference to the relevant drawings. Preferred embodiments of the present disclosure are shown in the drawings. However, the present disclosure can be implemented in many different manners and is not limited to the embodiments described herein. Rather, the purpose of providing these embodiments is to make the present disclosure more thorough and comprehensive.

Unless otherwise defined, all technical and scientific terms used herein have the same meaning as commonly understood by one of ordinary skill in the technical field to which the present disclosure belongs. The terms used in the specification of the present disclosure are only for the purpose of describing specific embodiments, and are not intended to limit the present disclosure.

It should be appreciated that when an element or a layer is referred to as being “on”, “adjacent to”, “connected to”, or “coupled to” another element or layer, it may be directly on, adjacent to, connected to, or coupled to the other element or layer, or there may exist an intermediate element or layer. Conversely, when an element is referred to as being “directly on”. “directly adjacent to”, “directly connected to” or “directly coupled to” another element or layer, there is no intermediate element or layer. It should be understood that the terms first, second, third, etc., may be utilized to describe various elements, components, regions, layers, conductivity types and/or portions, but these elements, components, regions, layers, conductivity types and/or portions should not be limited by these terms. These terms are merely utilized to distinguish one element, component, region, layer, conductivity type or portion from another element, component, region, layer, conductivity type or portion. Thus, a first element, component, region, layer or portion discussed below may represent a second element, component, region, layer or portion without departing from the teaching of the present disclosure. For example, a first conductivity type can be replaced with a second conductivity type; similarly, a second conductivity type can be replaced with a first conductivity type; and a first conductivity type is different from a second conductivity type. For instance, a first conductivity type can be P-type and a second conductivity type can be N-type; or a first conductivity type can be N-type and the second conductivity type can be P-type.

Spatial relational terms, such as “under”, “down”, “below”, “beneath”, “on”, “above”, etc., can be utilized herein to describe a relationship between one element or feature and another element or feature shown in the drawings. It will be appreciated that the spatially relative terms further includes different orientations of devices in use and operation in addition to the orientation depicted in the drawings. For example, if the device in the drawings flips, elements or features described as “below” or “under” or “beneath” other elements or features would then be oriented “above” the other elements or features. Thus, the exemplary terms “under” and “below” may include both orientations of up and down. In addition, a device may include other orientations (e.g., rotated 90 degrees or other orientations), and the spatial description terms used herein are interpreted accordingly.

When used herein, the singular forms such as “a”, “an” and “the” may also include the plural forms unless the context clearly dictates otherwise. It should also be appreciated that the terms “comprising/comprising” or “having”, etc., indicate the existence of features, integers, steps, operations, components, portions or combinations thereof, but do not exclude the existence or addition of one or more other features, integers, steps, operations, components, portions or combinations thereof. Meanwhile, in the specification, the term “and/or” includes any and all combinations of the related listed items.

FIG. 1 is a schematic structure diagram of an electrostatic protection structure according to an embodiment. The electrostatic protection structure 10 includes a substrate 100, a buried layer 200, a first deep well 300, a second deep well 400, and a third deep well 500.

In the present embodiment, the substrate 100 has a first conductivity type, and a buried layer 200 is injected into and formed in the substrate 100. The buried layer 200 has a second conductivity type, and the second conductivity type is opposite to the first conductivity type. Exemplarily, in the embodiment, the first conductivity type is P-type, and the second conductivity type is N-type.

In the embodiment, the first deep well 300 is located in the buried layer 200 and is floating, and has the first conductivity type.

The first deep well 300 and the buried layer 200 have opposite conductivity types, and have different doping concentration gradients, so that a PN junction is formed between the first deep well 300 and the buried layer 200, and then one of potential paths for the electrostatic discharge is formed between the first deep well 300 and the buried layer 200 when the electrostatic protection structure is connected to an electrostatic voltage.

An upper surface layer of the first deep well 300 is provided with a first well region 310 and a second well region 320 which are isolated from each other and are floating. Both the first well region 310 and the second well region 320 have the second conductivity type. An upper surface layer of the first well region 310 is provided with a first heavily doped region 311 and a second heavily doped region 312 isolated from each other. An upper surface layer of the second well region 320 is provided with a third heavily doped region 321 and a fourth heavily doped region 322 isolated from each other. The first heavily doped region 311, the second heavily doped region 312, the third heavily doped region 321 and the fourth heavily doped region 322 have the first conductivity type. The first heavily doped region 311 is led out as a first electrode J1 and is connected to an electrostatic port H. The second heavily doped region 312 is led out as a second electrode J2. The third heavily doped region 321 is led out as a third electrode J3 and is electrically connected to the second electrode J2. The fourth heavily doped region 322 is led out as a fourth electrode J4.

The electrostatic port H is a port that is connected to a unidirectional or bidirectional withstand voltage, and is configured to input an electrostatic voltage. The electrostatic voltage may be, for example, high-voltage static electricity. When the unidirectional withstand voltage is required, the electrostatic protection structure of the embodiment can perform forward withstand voltage or reverse withstand voltage. When the bidirectional withstand voltage is required, the electrostatic protection structure of the embodiment can perform the forward withstand voltage and the reverse withstand voltage, to discharge the connected static electricity. The fourth electrode J4 serves as an electrostatic port L of the electrostatic protection structure.

Since the conductivity type of the first deep well 300 is opposite to the conductivity type of the first well region 310 and the second well region 320, and the doping concentration gradient of the first deep well 300 is different from the doping concentration gradients of the first well region 310 and the second well region 320, the PN junctions can be formed between the first deep well 300 and the first well region 310, and between the first deep well 300 and the second well region 320. Accordingly, when the electrostatic port H inputs the electrostatic voltage, one of potential paths for the electrostatic discharge can be formed between the first well region 310 and the first heavily doped region 311, and between the first well region 310 and the second heavily doped region 312.

Since the conductivity type of the first well region 310 is opposite to the conductivity type of the first heavily doped region 311 and the second heavily doped region 312, and the doping concentration gradient of the first well region 310 is different from the doping concentration gradients of the first heavily doped region 311 and the second heavily doped region 312, a PN junction can be formed between the first well region 310 and the first heavily doped region 311, a PN junction can be formed between the first well region 310 and the second heavily doped region 312, and a voltage bias of the PN junction between the first well region 310 and the first heavily doped region 311 is opposite to a voltage bias of the PN junction formed between the first well region 310 and the second heavily doped region 312. Accordingly, when the electrostatic port H inputs the electrostatic voltage, one of potential paths for the electrostatic discharge can be formed between the first well region 310 and the first heavily doped region 311, and between the first well region 310 and the second heavily doped region 312.

Since the conductivity type of the second well region 320 is opposite to the conductivity type of the third heavily doped region 321 and the fourth heavily doped region 322, and the doping concentration gradient of the second well region 320 is different form the doping concentration gradients of the third heavily doped region 321 and the fourth heavily doped region 322, a PN junction can be formed between the second well region 320 and the third heavily doped region 321, a PN junction can be formed between the second well region 320 and the fourth heavily doped region 322, and the voltage bias of the PN junction between the second well region 320 and the third heavily doped region 321 is opposite to the voltage bias of the PN junction formed between the second well region 320 and the fourth heavily doped region 322. Accordingly, when the electrostatic port H inputs the electrostatic voltage, one of potential paths for the electrostatic discharge is formed between the second well region 320 and the third heavily doped region 321, and between the second well region 320 and the fourth heavily doped region 322.

Since the first heavily doped region 311 is led out as the first electrode J1 and is connected to the electrostatic port H, the second heavily doped region 312 is led out as the second electrode J2, the third heavily doped region 321 is led out as the third electrode J3 and is electrically connected to the second electrode J2, and the fourth heavily doped region 322 is led out as the fourth electrode J4. When the electrostatic port H inputs the electrostatic voltage and the PN junction between the first well region 310 and the second heavily doped region 312 is broken down, a current is conducted between the third electrode J3 and the second electrode J2. A potential path for the electrostatic discharge of different voltage biases are formed among the first heavily doped region 311, the first well region 310, the second heavily doped region 312, the third heavily doped region 321, the second well region 320 and the fourth heavily doped region 322.

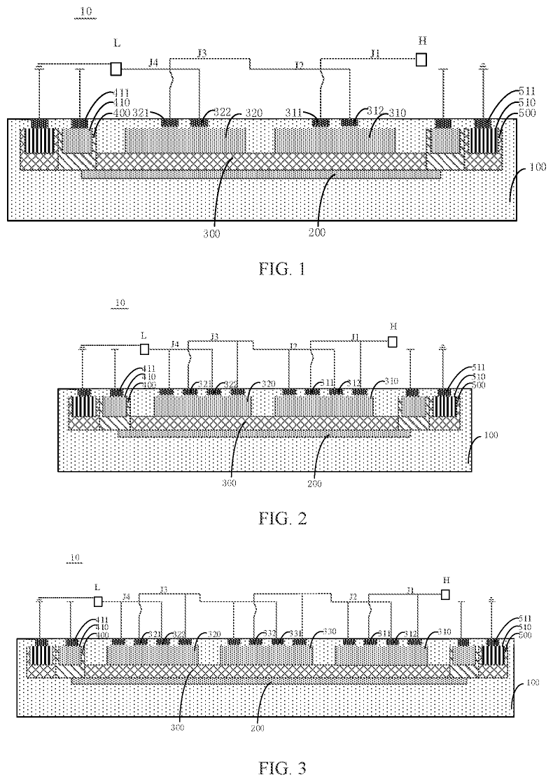

In some embodiments, as shown in FIG. 2, there exists at least two first heavily doped regions 311, at least two second heavily doped regions 312, at least two third heavily doped regions 321, and at least two fourth heavily doped region 322 (in FIG. 2, the number of each is two as an example). A plurality of first heavily doped regions 311 are isolated from each other, a plurality of second heavily doped regions 312 are isolated from each other, a plurality of third heavily doped regions 321 are isolated from each other, and a plurality of fourth heavily doped regions 322 are isolated from each other. The plurality of first heavily doped regions 311 are electrically connected to serve as the first electrode J1, the plurality of second heavily doped regions 312 are electrically connected to serve as the second electrode J2, the plurality of third heavily doped regions 312 are electrically connected to each other to serve as the third electrode J3, and the plurality of fourth heavily doped regions 322 are electrically connected to each other to serve as the fourth electrode J4. Therefore, each electrode corresponds to a plurality of heavily doped regions, which is beneficial to improving the electrostatic discharge capability of each electrode during the electrostatic protection process.

The number of the first heavily doped regions 311, the number of the second heavily doped regions 312, the number of the third heavily doped regions 321, and the number of the fourth heavily doped regions 322 can be set according to actual requirements, for example, can be set according to the magnitude of the actual electrostatic voltage. When the electrostatic voltage is higher, a larger quantity can be set within an acceptable range of the product, and when the electrostatic voltage is lower, a smaller quantity can be set.

In some embodiments, when the first conductivity type is P-type and the second conductivity type is N-type, and when the electrostatic port H inputs an electrostatic voltage, the first heavily doped region 311, the first well region 310 and the second heavily doped region 312 together form a first PNP transistor, the third heavily doped region 321, the second well region 320 and the fourth heavily doped region 322 together form a second PNP transistor, and the first PNP transistor is connected to the second PNP transistor in series. By using the PNP transistor to perform the ESD protection, the maintaining voltage can be made higher.

Further, when the electrostatic port H inputs a positive voltage, the first electrode J1 is an emitter of the first PNP transistor, the second electrode J2 is a collector of the first PNP transistor, and the first well region 310 is a floating base of the first PNP transistor, the third electrode J3 is an emitter of the second PNP transistor, the fourth electrode J4 is a collector of the second PNP transistor, and the second well region 320 is a floating base of the second PNP transistor. When the electrostatic port H inputs the positive voltage, the electrostatic protection structure is in a forward withstand voltage mode, through the forward bias of the emitter and the floating base of the first PNP transistor, which results in that the emitter and the floating base of the first PNP transistor are broken down, and an avalanche current caused by the breakdown passes through the emitter of the second PNP transistor, to implement the series connection between the first PNP transistor to the second PNP transistor, and form a main path for the electrostatic discharge of the forward electrostatic protection, thereby achieving the anti-high voltage requirement.

Further, when the electrostatic port H inputs a negative voltage, the first electrode J is the collector of the first PNP transistor, the second electrode J2 is the emitter of the first PNP transistor, the third electrode J3 is the collector of the second PNP transistor, and the fourth electrode J4 is the emitter of the second PNP transistor.

Therefore, when different electrostatic voltages are inputted, the collectors and emitters of the first PNP transistor and the second PNP transistor can be interchanged, which is easier to implement the consistency of the bidirectional withstand voltage.

It should be noted that, in other embodiments, it is not limited to form a PNP transistor, and other device types of electrostatic protection structures can be formed by arranging other layer structures, such as forming a PMOS device, specifically, a GDPMOS device.

In some embodiments, as shown in FIG. 3, at least one fifth well region 330 is further provided between the first well region 310 and the second well region 320 in the upper surface layer of the first deep well 300 (FIG. 3 shows an added fifth well region 330 based on FIG. 2). The fifth well region 330 is isolated from the first well region 310 and the second well region 320. The fifth well region 330 has a second conductivity type. The upper surface layer of each fifth well region 330 is provided with a seventh heavily doped region 331 and an eighth heavily doped region of the first conductivity type. The seventh heavily doped region 331 of each fifth well region 330 is electrically connected to the eighth heavily doped region 332 of an adjacent fifth well region 330. The seventh heavily doped region 331 adjacent to the first well region 310 is electrically connected to the second heavily doped region 312. The eighth heavily doped region 332 adjacent to the second well region 320 is electrically connected to the third heavily doped region 321. Accordingly, electrostatic discharge potential paths with different voltage biases are formed among the first heavily doped region 311, the first well region 310, the second heavily doped region 312, the seventh heavily doped region 331, the fifth well region 330, the eighth heavily doped region 332, the third heavily doped region 321, the second well region 320 and the fourth heavily doped region 322.

When the first conductivity type is P-type, the second conductivity type is N-type, and the electrostatic port H inputs the electrostatic voltage, the first heavily doped region 311, the first well region 310 and the second heavily doped region 312 together form the first PNP transistor. The third heavily doped region 321, the second well region 320 and the fourth heavily doped region 322 together form the second PNP transistor. The seventh heavily doped region 331, the fifth well region 330 and the eighth heavily doped region 332 together form the third PNP transistor. The first PNP transistor, a plurality of third PNP transistors, and the second PNP transistor are connected to each other in series. When the electrostatic port H inputs the positive voltage, the electrostatic protection structure is in the forward withstand voltage mode, through the forward bias of the emitter and the floating base of the first PNP transistor, which results in that the floating base and the emitter of the first PNP transistor are broken down, and the avalanche current caused by the breakdown passes through the emitter of the third PNP transistor. Through the forward bias of the emitter and the floating base of the third PNP transistor, which results in that the floating base and the emitter of the second PNP transistor are broken down, and the avalanche current caused by the breakdown passes through the emitter of the second PNP transistor, so that the first PNP transistor is connected to the third PNP transistor in series, and the third PNP transistor is connected to the second PNP transistor in series, to form a main path for the electrostatic discharge of the forward electrostatic protection, thereby further improving the electrostatic withstand voltage capability, and meanwhile having a higher electrostatic maintaining voltage and being less prone to a latch-up effect.

The number of the third PNP transistor can be set according to different gears of the electrostatic voltage, and the higher the gear of the electrostatic voltage, a larger number of third PNP transistors can be set to solve the electrostatic protection of a higher gear.

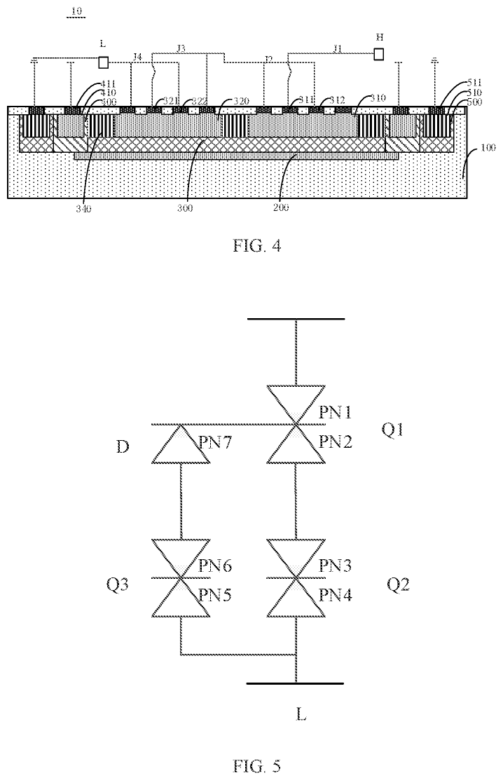

In some embodiments, as shown in FIG. 4, the upper surface layer of the first deep well 300 is further provided with a plurality of sixth well regions 340, and the plurality of sixth well regions 340 are arranged alternatively with the first well region 310 and the second well region 320. The sixth well region 340 has the first conductivity type.

The sixth well regions 340 are arranged alternatively with the first well region 310 and the second well region 320, and has the opposite conductivity type to and the same doping concentration gradient as the first well region 310 and the second well region 320, so that the sixth well region 340 can be configured to isolate the first well region 310 from the second well region 320 to prevent the first well region 310 and the second well region 320 from interacting with each other during the process of the electrostatic withstand voltage. Further, the sixth well region 340 adjacent to the second deep well 400 is located between the first well region 310 and the third well region, since the sixth well region 340 has the opposite conductivity type to and the same doping concentration gradient as the first well region 310 and the second well region 320, so that the sixth well region 340 can be configured to isolate the first well region 310 from the third well region, thereby avoiding the interaction effect between the first well region 310 and the third well region during the process of the electrostatic withstand voltage.

In the embodiment, the second deep well 400 is located on the upper surface of the buried layer 200 and a partial region thereof is in contact with the substrate 100, and the second deep well 400 has the second conductivity type. The second deep well 400 is adjacent to the first deep well 300 and is located at a periphery of the first deep well 300.

The second deep well 400 is located on the upper surface of the buried layer 200 and a partial region thereof is in contact with the substrate 100, and is adjacent to the first deep well 300. Since the second deep well 400 and the buried layer 200 have an opposite conductivity type to and a different doping concentration gradient from the first deep well 300 and the substrate 100, PN junctions can be formed between the second deep well 400 and the substrate 100, and between the buried layer 200 and the substrate 100, and PN junctions can be formed between the second deep well 400 and the first deep well 300, and between the buried layer 200 and the first deep well 300. After the voltage is inputted through the electrostatic port H, one of the potential paths for the electrostatic discharge can be formed between the second deep well 400 and the substrate 100, between the buried layer 200 and the substrate 100, between the second deep well 400 and the first deep well 300, and between the buried layer 200 and the first deep well 300. The second deep well 400 is located between the first deep well 300 and the third deep well 500, and has an opposite conductivity type to the first deep well 300 and the third deep well 500. Accordingly, the second deep well 400 can be configured to isolate the first deep well 300 from the third deep well 500.

The upper surface layer of the second deep well 400 is provided with a third well region 410, and the third well region 410 has the second conductivity type. The upper surface layer of the third well region 410 is provided with a floating fifth heavily doped region 411. The fifth heavily doped region 411 has the second conductivity type. The fifth heavily doped region 411 is floating and led out as an isolation port of the electrostatic protection structure. Exemplarily, a width of a sidewall of the third well region 410 is smaller than a width of a sidewall of the second deep well 400, so that the third well region 410 is isolated from the adjacent first deep well 300 and the third deep well 500 respectively.

In some embodiments, the second deep well 400 has a circular structure and surrounds the periphery of the first deep well 300. The third deep well 500 has a circular structure and surrounds the periphery of the second deep well 400, so that the second deep well 400 and the third deep well 500 form a double-circle structure. While forming the discharge path for the electrostatic discharge with the first deep well 300 inside, the interaction effect between the wells with the same conductivity type can be effectively avoided, and the electrostatic protection performance can be effectively improved.

In the embodiment, the third deep well 500 is located in the buried layer 200 and is in contact with the substrate 100, and has the first conductivity type. The third deep well 500 is adjacent to the second deep well 400 and is located at the periphery of the second deep well 400.

The third deep well 500 is located in the buried layer 200 and is completely in contact with the substrate 100, and is adjacent to the second deep well 400. Since the third deep well 500 and the substrate 100 have the opposite conductivity type to the second deep well 400 and the buried layer 200, PN junctions can be formed between the third deep well 500 and the second deep well 400, between the third deep well 500 and the buried layer 200, between the substrate 100 and the second deep well 400, and between the substrate 100 and the buried layer 200. After the voltage is inputted through the electrostatic port H, one of the potential paths for the electrostatic discharge can be formed between the third deep well 500 and the second deep well 400, between the third deep well 500 and the buried layer 200, between the substrate 100 and the second deep well 400, and between the substrate 100 and the buried layer 200.

The upper surface layer of the third deep well 500 is provided with a fourth well region 510, and the fourth well region 510 has the first conductivity type. The upper surface layer of the fourth well region 510 is provided with a sixth heavily doped region 511, and the sixth heavily doped region 511 has the first conductivity type. The sixth heavily doped region 511 is led out and grounded together with the fourth electrode J4, that is, the sixth heavily doped region 511 is led out and connected to the substrate together with the fourth electrode J4. Exemplarily, a width of a sidewall of the fourth well region 510 is less than a width of a sidewall of the third deep well 500, so that the fourth well region 510 is isolated from the adjacent second deep well 400.

Since the conductivity type of the fourth well region 510, the third deep well 500, and the substrate 100 is opposite to the conductivity type of the buried layer 200, the second deep well 400 and the third well region 410, and the doping concentration gradient of the fourth well region 510, the third deep well 500 and the substrate 100 is different from that of the buried layer 200, the second deep well 400 and the third well region 410, a PN junction can be formed between any one of the fourth well region 510, the third deep well 500 and the substrate 100, and any one of the buried layer 200, the second deep well 400 and the third well region 410. Since the buried layer 200, the second deep well 400 and the third well region 410 have the opposite conductivity type to and different doping concentration gradient from the first deep well 300, a PN junction is formed between the first deep well 300 and any one of the buried layer 200, the second deep well 400 and the third well region 410.

Referring to FIG. 5, the electrostatic protection structure including two PNP transistors is taken as an example, the process of bidirectional electrostatic protection of the electrostatic protection structure is described below.

When the electrostatic port H inputs the positive voltage, the electrostatic protection structure is in the forward withstand voltage mode in which the PN junction formed between the first heavily doped region 311 and the floating first well region 310 (referring to PN1 in FIG. 5) is in a forward bias state, the PN junction formed between the first well region 310 and the second heavily doped region (referring to PN2 in FIG. 5) is in a reverse bias state, the PN junction formed between the third heavily doped region 321 and the second well region 320 (referring to PN3 in FIG. 5) is in the forward bias state, and the PN junction formed between the second well region 320 and the fourth heavily doped region (referring to PN4 in FIG. 5) is in the reverse bias state. When the PN junction formed between the first well region 310 and the second heavily doped region is broken down, the first heavily doped region 311, the first well region 310 and the second heavily doped region 312 together form the first PNP transistor Q1, the third heavily doped region 321, the second well region 320 and the fourth heavily doped region 322 together form the second PNP transistor Q2, the forward withstand voltage is applied through the first PNP transistor Q1 and the second PNP transistor Q2, and a higher electrostatic maintaining voltage is obtained without being prone to the latch-up effect.

When the electrostatic port H is connected to a negative voltage, the electrostatic protection structure is in a negative withstand voltage mode in which the grounded sixth heavily doped region 511 connected to the ground is equivalent to connecting to a positive voltage, so that the PN junction (referring to PN5 in FIG. 5) between any one of the fourth well region 510, the third deep well 500 and the substrate 100, and any one of the buried layer 200, the second deep well 400 and the third well region 410 is in the forward bias state, the PN junction (referring to PN6 in FIG. 5) between the first deep well 300 and any one of the buried layer 200, the second deep well 400 and the first deep well 300 is in a reverse bias state, and the PN junction between the first deep well 300 and the first well region 310 is in the forward bias state. As a result, the PN junctions between the second deep well 400 and the first deep well 300, and between the buried layer 200 and the first deep well 300 have a higher withstand voltage which is not lower than the breakdown voltage applied on the floating base and the emitter of the second PNP transistor Q2, so that the buried layer 200, the second deep well 400, and the third well region 410 are equivalent to the floating base, the fourth well region 510, the third deep well 500 and the substrate 100 are equivalent to the emitter, the first deep well 300 is equivalent to the collector; the buried layer 200, the second deep well 400, the third well region 410, the fourth well region 510, the third deep well 500, the substrate 100 and the first deep well 300 form a parasitic PNP transistor Q3 The first deep well 300 is equivalent to an anode of a diode, the first well region 310 is equivalent to a cathode of the diode D, and the first deep well 300 and the first well region 310 form the diode D. Accordingly, the reverse withstand voltage can be applied through the parasitic PNP transistor Q3 and the diode D, and the electrostatic protection structure has a higher electrostatic maintaining voltage and is less prone to the latch-up effect.

Therefore, when the electrostatic protection structure is in the forward withstand voltage mode, the capability of the connection in series between the first PNP transistor Q1 and the second PNP transistor Q2 is utilized to apply the forward withstand voltage, and the electrostatic protection structure has a higher electrostatic maintaining voltage and is less prone to the latch-up effect. When the electrostatic protection structure is in the negative withstand voltage mode, the capability of connection in series between the first PNP transistor Q1 and the second PNP transistor Q2 is also used. In addition, the high withstand voltage PNP transistor Q3 and the diode D which are connected to each in parallel are also used, accordingly the electrostatic protection structure has a higher electrostatic maintaining voltage and is less prone to the latch-up effect. Therefore, the electrostatic protection structure can implement the consistency of the withstand voltages in both directions.

The electrostatic protection structure provided in the embodiment includes a substrate 100 of a first conductivity type, a buried layer 200 of a second conductivity type, a first deep well 300 of a first conductivity type, a second deep well 400 of a second conductivity type, and a third deep well 500 of a first conductivity type. The first deep well 300 is provided with well regions having opposite conductivity types, and heavily doped regions having the same conductivity type. The second deep well 400 and the third deep well 500 are respectively provided with well regions having the same conductivity type and heavily doped regions having the same conductivity type. The first deep well 300, the first well region 310 and the second well region 320 are floating. The first heavily doped region 311 is led out and is connected to an electrostatic voltage. The sixth heavily doped region 511 is grounded. When the electrostatic port H inputs a positive voltage, the electrostatic protection structure is in the forward withstand voltage mode. The first heavily doped region 311, the first well region 310 and the second heavily doped region 312 together form the first PNP transistor Q1. The third heavily doped region 321, the second well region 320, and the fourth heavily doped region 322 together form the second PNP transistor Q2. The forward withstand voltage is applied through the first PNP transistor Q1 and the second PNP transistor Q2, a higher electrostatic maintaining voltage is obtained, and the latch-up effect is not easy to occur. When the electrostatic port H inputs a negative voltage, the electrostatic protection structure is in the reverse withstand voltage mode. The buried layer 200, the second deep well 400, the third well region 410, the fourth well region 510, the third deep well 500, the substrate 100 and the first deep well 300 form a parasitic PNP transistor. The first deep well 300 and the first well region 310 form a diode, and the reverse withstand voltage can be applied through the parasitic PNP transistor and the diode. Meanwhile the electrostatic protection structure is allowed to have a higher electrostatic maintaining voltage and is less prone to the latch-up effect. Accordingly, the electrostatic protection structure can implement the consistency of the withstand voltages in both directions.

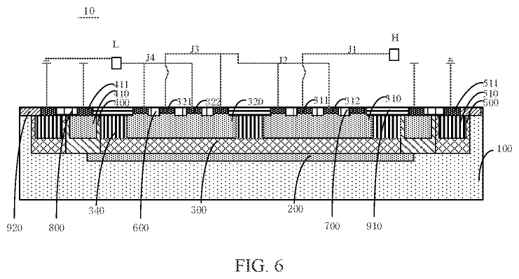

FIG. 6 is a schematic structure diagram of an electrostatic protection structure according to an embodiment. Based on the electrostatic protection structure in the above embodiments, the electrostatic protection structure in the embodiment further includes a first isolation structure, a second isolation structure, a third isolation structure, and a fourth isolation structure.

In the embodiment, the first isolation structure 600 is located in the upper surface layer of the first deep well 300, and passes through the upper surface of the first deep well 300 to the first well region 310. The first isolation structure 600 is arranged alternatively with the first heavily doped region 311 and second heavily doped region 312, to isolate the first heavily doped region 311 from the second heavily doped region 312, thereby preventing the interaction effect between the first heavily doped region 311 and the second heavily doped region 312 in the process of electrostatic discharge.

In the embodiment, the second isolation structure 700 is located in the upper surface layer of the first deep well 300, and passes through the upper surface of the first deep well 300 to the second well region 320. The second isolation structure 700 is arranged alternatively with the third heavily doped region 321 and the fourth heavily doped region 322, to isolate the third heavily doped region 321 from the fourth heavily doped region 322, thereby preventing the interaction effect between the third heavily doped region 321 and the fourth heavily doped region 322 in the process of electrostatic discharge.

In the embodiment, the third isolation structures 800 are located in the upper surface layers of the second deep well 400 and the third deep well 500, and the third isolation structure 800 is located between the fifth heavily doped region 411 and the sixth heavily doped region 511, to isolate the fifth heavily doped region 411 from the sixth heavily doped region 511 to prevent the interaction effect between the fifth heavily doped region 411 and the sixth heavily doped region 511 in the process of electrostatic discharge.

In the embodiment, the fourth isolation structures 910 are located in the upper surface layer of the fourth well region 510, and are located between the first heavily doped region 311 and the fifth heavily doped region 411, and between the fourth heavily doped region 322 and the fifth heavily doped region 411, thereby isolating the first heavily doped region 311 from the fifth heavily doped region 411, to isolate the fourth heavily doped region 322 from the fifth heavily doped region 411, and further improving the isolation performance of the electrostatic protective structure.

In the embodiment, the fifth isolation structure 920 is located in the upper surface layer of the third deep well 500, and is configured to isolate the electrostatic protection structure from other devices, thereby further improving the isolation performance of the electrostatic protection structure.

In an embodiment, the first isolation structure 600, the second isolation structure 700, the third isolation structure 800, the fourth isolation structure 910 and the fifth isolation structure 920 may be shallow trench isolation structures.

The electrostatic protection structure in the embodiment can effectively improve the isolation performance of the device through the first isolation structure 600, the second isolation structure 700, the third isolation structure 800, the fourth isolation structure 910, and the fifth isolation structure 920.

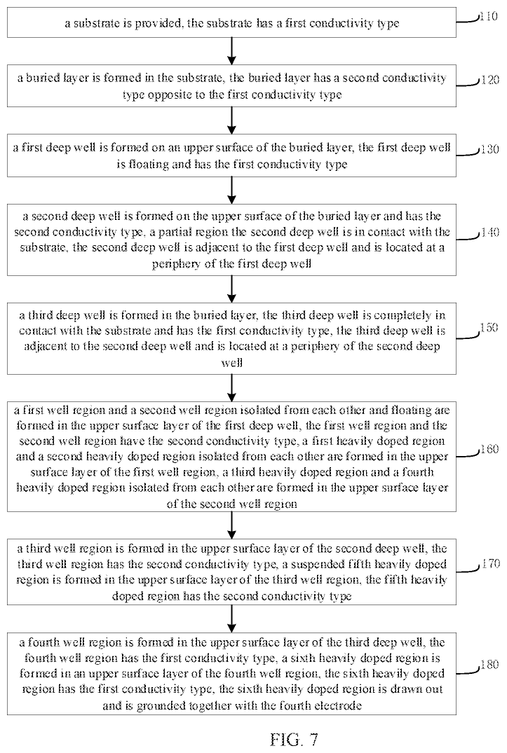

In an embodiment, a manufacture method for an electrostatic protection structure is provided, which is configured to manufacture the electrostatic protection structure as described in the above embodiments. As shown in FIG. 7, the manufacture method includes following steps.

Step 110: a substrate having a first conductivity type is provided.

Step 120: a buried layer having a second conductivity type opposite to the first conductivity type is formed in the substrate.

Step 130: a first deep well is formed on an upper surface of the buried layer. The first deep well is floating and has the first conductivity type.

Step 140: a second deep well is formed on the upper surface of the buried layer and has the second conductivity type. A partial region the second deep well is in contact with the substrate, and the second deep well is adjacent to the first deep well and is located at a periphery of the first deep well.

Step 150: a third deep well is formed in the buried layer. The third deep well is completely in contact with the substrate and has the first conductivity type, and the third deep well is adjacent to the second deep well and is located at a periphery of the second deep well.

Step 160: a first well region and a second well region isolated from each other and floating are formed in the upper surface layer of the first deep well. The first well region and the second well region have the second conductivity type. A first heavily doped region and a second heavily doped region isolated from each other are formed in the upper surface layer of the first well region. A third heavily doped region and a fourth heavily doped region isolated from each other are formed in the upper surface layer of the second well region.

The first heavily doped region, the second heavily doped region, the third heavily doped region and the fourth heavily doped region have the first conductivity type. The first heavily doped region is led out as a first electrode and is connected to an electrostatic port. The second heavily doped region is led out as a second electrode. The third heavily doped region is led out as a third electrode and is electrically connected to the second electrode. The fourth heavily doped region is led out as a fourth electrode.

Step 170: a third well region is formed in the upper surface layer of the second deep well. The third well region has the second conductivity type. A floating fifth heavily doped region is formed in the upper surface layer of the third well region. The fifth heavily doped region has the second conductivity type.

Step 180: a fourth well region is formed in the upper surface layer of the third deep well. The fourth well region has the first conductivity type. A sixth heavily doped region is formed in an upper surface layer of the fourth well region. The sixth heavily doped region has the first conductivity type. The sixth heavily doped region is led out and is grounded together with the fourth electrode.

The steps 110 to 180 are utilized to manufacture the electrostatic protection structure described in the embodiments of FIG. 1-FIG. 2, and as for the related description, reference can be made to the related description in the embodiments shown in FIGS. 1-2. The method of “forming” can adopt the existing manufacture method, which is not limited herein.

The steps 130 to 50 may be performed simultaneously or sequentially, and the steps 160 to 180 may be performed simultaneously or sequentially.

The manufacture method provided in the embodiment can manufacture an electrostatic protection structure capable of applying the bidirectional withstand voltage, and meanwhile the electrostatic protection structure has a higher electrostatic maintaining voltage and is less prone to the latch-up effect.

In some embodiments, the manufacture method further includes:

Step 190: at least one fifth well region is formed in the upper surface layer of the first deep well and between the first well region and the second well region. The fifth well region is isolated from the first well region and the second well region respectively. The fifth well region has the second conductivity type. A seventh heavily doped region and an eighth heavily doped region of the first conductivity type are formed in the upper surface layer of each fifth well region. The seventh heavily doped region of each fifth well region is electrically connected to the eighth heavily doped region of an adjacent fifth well region. The seventh heavily doped region adjacent to the first well region is electrically connected to the second heavily doped region. The eighth heavily doped region adjacent to the second well region is electrically connected to the third heavily doped region.

The step 190 is configured to manufacture the electrostatic protection structure described in the embodiment shown in FIG. 3. For related description, reference can be made to the related description in the embodiment of FIG. 3. The method of “forming” can adopt the existing manufacture method, which is not limited herein.

In some embodiments, the manufacture method further includes:

step 200: a plurality of sixth well regions are formed in the upper surface layer of the first deep well. The plurality of sixth well regions are arranged alternatively with the first well region and the second well region, and the sixth well regions have the first conductivity type.

The step 200 is configured to manufacture the electrostatic protection structure described in the embodiment of FIG. 4. For related description, reference can be made to the related description in the embodiment of FIG. 4. The step 200 may be performed simultaneously or sequentially with the steps 130 to 150 in the above embodiment. The method of “forming” can adopt the existing manufacture method, which is not limited herein.

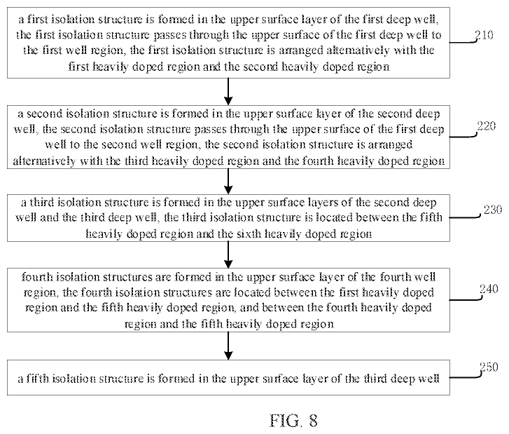

In an embodiment, as shown in FIG. 8, the manufacture method further includes following steps.

Step 210: a first isolation structure is formed in the upper surface layer of the first deep well. The first isolation structure passes through the upper surface of the first deep well to the first well region, and the first isolation structure is arranged alternatively with the first heavily doped region and the second heavily doped region.

Step 220: a second isolation structure is formed in the upper surface layer of the second deep well. The second isolation structure passes through the upper surface of the first deep well to the second well region, and the second isolation structure is arranged alternatively with the third heavily doped region and the fourth heavily doped region.

Step 230: a third isolation structure is formed in the upper surface layers of the second deep well and the third deep well. The third isolation structure is located between the fifth heavily doped region and the sixth heavily doped region.

Step 240: fourth isolation structures are formed in the upper surface layer of the fourth well region. The fourth isolation structures are located between the first heavily doped region and the fifth heavily doped region, and between the fourth heavily doped region and the fifth heavily doped region.

Step 250: a fifth isolation structure is formed in the upper surface layer of the third deep well.

The steps 210 to 250 are configured to manufacture the electrostatic protection structure described in the embodiment of FIG. 6. For the related description, reference can be made to the related description in the embodiment of FIG. 6. The steps 210 to 250 can be performed simultaneously or sequentially. The method of “forming” can adopt the existing manufacture method, which is not limited herein.

In the description of the specification, the description of the reference terms “in some embodiments”, “other embodiments” and the like mean that specific features, structures, materials or features described in connection with the embodiments or examples are included in at least one embodiment or example of the present disclosure. In the specification, the schematic description of the above terms does not necessarily refer to the same embodiment or example.

The technical features of the above-mentioned embodiments can be combined arbitrarily. For the sake of concise description, not all possible combinations of the technical features of the above-mentioned embodiments are described. However, as long as there is no contradiction in the combinations of these technical features, those combinations should be considered to be within the scope of the present disclosure.

The above-mentioned embodiments merely show some implementation modes of the present disclosure, and the description thereof is relatively specific and detailed, but should not be construed as limiting the scope of the patent disclosure. It should be noted that those skilled in the art can make several modifications and improvements without departing from the concept of the present disclosure, and these all belong to the protection scope of the present disclosure. Therefore, the scope of protection of the patent disclosure should be subject to the appended claims.

What is claimed is:

1. An electrostatic protection structure, comprising:
a substrate, having a first conductivity type;
a buried layer, located in the substrate and having a second conductivity type opposite to the first conductivity type;
a first deep well, located on an upper surface of the buried layer and floating, and having the first conductivity type;
a second deep well, located on the upper surface of the buried layer, and having the second conductivity type, a partial region of the second deep well being in contact with the substrate, the second deep well being adjacent to the first deep well and being located at a periphery of the first deep well; and
a third deep well, located in the buried layer and completely in contact with the substrate, having the first conductivity type, the third deep well being adjacent to the second deep well and being located at a periphery of the second deep well;
wherein an upper surface layer of the first deep well is provided with a first well region and a second well region which are isolated from each other and are floating, both the first well region and the second well region have the second conductivity type, an upper surface layer of the first well region is provided with a first heavily doped region and a second heavily doped region isolated from each other, an upper surface layer of the second well region is provided with a third heavily doped region and a fourth heavily doped region isolated from each other, the first heavily doped region, the second heavily doped region, the third heavily doped region and the fourth heavily doped region have the first conductivity type, the first heavily doped region is led out as a first electrode and is connected to an electrostatic port, the second heavily doped region is led out as a second electrode, the third heavily doped region is led out as a third electrode and is electrically connected to the second electrode, and the fourth heavily doped region is led out as a fourth electrode;
wherein an upper surface layer of the second deep well is provided with a third well region, the third well region has the second conductivity type, and an upper surface layer of the third well region is provided with a floating fifth heavily doped region having the second conductivity type; and
wherein an upper surface layer of the third deep well is provided with a fourth well region, the fourth well region has the first conductivity type, an upper surface layer of the fourth well region is provided with a sixth heavily doped region, the sixth heavily doped region has the first conductivity type, and the sixth heavily doped region is led out and is grounded together with the fourth electrode.

2. The electrostatic protection structure according to claim 1, wherein the first conductivity type is a P-type, and the second conductivity type is a N-type, and
wherein when the electrostatic port inputs an electrostatic voltage,
the first heavily doped region, the first well region and the second heavily doped region together form a first PNP transistor; the third heavily doped region, the second well region and the fourth heavily doped region together form a second PNP transistor; and the first PNP transistor is connected to the second PNP transistor in series.

3. The electrostatic protection structure according to claim 2, wherein when the electrostatic voltage is a positive voltage,
the first electrode serves as an emitter of the first PNP transistor, the second electrode serves as a collector of the first PNP transistor, and the first well region serves as a base of the first PNP transistor; and
the third electrode serves as an emitter of the second PNP transistor, the fourth electrode serves as a collector of the second PNP transistor, and the second well region serves as a base of the second PNP transistor.

4. The electrostatic protection structure according to claim 2, wherein when the electrostatic voltage is a negative voltage,
the first electrode serves as a collector of the first PNP transistor, the second electrode serves as an emitter of the first PNP transistor, and the first well region serves as a base of the first PNP transistor; and
the third electrode is a collector of the second PNP transistor, the fourth electrode is an emitter of the second PNP transistor, and the second well region serves as a base of the second PNP transistor.

5. The electrostatic protection structure according to claim 1, wherein there exists at least two first heavily doped regions, at least two second heavily doped regions, at least two third heavily doped regions, and at least two fourth heavily doped regions; and
wherein a plurality of the first heavily doped regions are isolated from each other, a plurality of the second heavily doped regions are isolated from each other, a plurality of the third heavily doped regions are isolated from each other, and a plurality of the fourth heavily doped regions are isolated from each other.

6. The electrostatic protection structure according to claim 5, wherein the plurality of the first heavily doped regions are electrically connected to each other as the first electrode, the plurality of the second heavily doped regions are electrically connected to each other as the second electrode, the plurality of the third heavily doped regions are electrically connected to each other as the third electrode, and the plurality of the fourth heavily doped regions are electrically connected to each other as the fourth electrode.

7. The electrostatic protection structure according to claim 1, wherein at least one fifth well region is provided between the first well region and the second well region in the upper surface layer of the first deep well, the fifth well region is respectively isolated from the first well region and the second well region, and the fifth well region has the second conductivity type; and
wherein an upper surface layer of each fifth well region is provided with a seventh heavily doped region and an eighth heavily doped region of the first conductivity type, the seventh heavily doped region of each fifth well region is electrically connected to an eighth heavily doped region of an adjacent fifth well region, the seventh heavily doped region adjacent to the first well region is electrically connected to the second heavily doped region, and the eighth heavily doped region adjacent to the second well region is electrically connected to the third heavily doped region.

8. The electrostatic protection structure according to claim 7, wherein the first conductivity type is a P-type, and the second conductivity type is a N-type; and
wherein when the electrostatic port inputs an electrostatic voltage,
the first heavily doped region, the first well region and the second heavily doped region together form a first PNP transistor; the third heavily doped region, the second well region and the four heavily doped region together form a second PNP transistor; the seventh heavily doped region, the fifth well region and the eighth heavily doped region together form a third PNP transistor; and the first PNP transistor, a plurality of the third PNP transistors, and the second PNP transistors are connected to each other in series.

9. The electrostatic protection structure according to claim 1, wherein the upper surface layer of the first deep well is further provided with a plurality of sixth well regions, the plurality of sixth well regions are arranged alternatively with the first well region and the second well region, and the sixth well regions have the first conductivity type.

10. The electrostatic protection structure according to claim 1, wherein the second deep well is a circular structure and surrounds the periphery of the first deep well, and the third deep well is a circular structure and surrounds the periphery of the second deep well.

11. The electrostatic protection structure according to claim 1, wherein a width of a sidewall of the third well region is less than a width of a sidewall of the second deep well.

12. The electrostatic protection structure according to claim 1, wherein a width of a sidewall of the fourth well region is less than a width of a sidewall of the third deep well.

13. The electrostatic protection structure according to claim 1, further comprising:
a first isolation structure, located in the upper surface layer of the first deep well, and passing through an upper surface of the first deep well to the first well region, wherein the first isolation structure is arranged alternatively with the first heavily doped region and the second heavily doped region; and
a second isolation structure, located in the upper surface layer of the first deep well, and passing through the upper surface of the first deep well to the second well region, wherein the second isolation structure is arranged alternatively with the third heavily doped region and the fourth heavily doped region.

14. The electrostatic protection structure according to claim 1, further comprises:
third isolation structures, located in upper surface layers of the second deep well and the third deep well, and located between the fifth heavily doped region and the sixth heavily doped region;
fourth isolation structures, located in the upper surface layer of the fourth well region, and located between the first heavily doped region and the fifth heavily doped region and between the fourth heavily doped region and the fifth heavily doped region.

15. A manufacture method for an electrostatic protection structure, comprising:
providing a substrate having a first conductivity type;
forming a buried layer in the substrate, the buried layer having a second conductivity type opposite to the first conductivity type;
forming a first deep well on an upper surface of the buried layer, the first deep well being floating and having the first conductivity type;
forming a second deep well on the upper surface of the buried layer, a partial region the second deep well being in contact with the substrate, the second deep having the second conductivity type, being adjacent to the first deep well and being located at a periphery of the first deep well;
forming a third deep well in the buried layer, the third deep well being completely in contact with the substrate and having the first conductivity type, the third deep well being adjacent to the second deep well and being located at a periphery of the second deep well;
forming a first well region and a second well region isolated from each other and floating in the upper surface layer of the first deep well, both the first well region and the second well region having the second conductivity type; forming a first heavily doped region and a second heavily doped region isolated from each other in the upper surface layer of the first well region; forming a third heavily doped region and a fourth heavily doped region isolated from each other in the upper surface layer of the second well region, wherein the first heavily doped region, the second heavily doped region, the third heavily doped region and the fourth heavily doped region have the first conductivity type, the first heavily doped region is led out as a first electrode and is connected to an electrostatic port, the second heavily doped region is led out as a second electrode, the third heavily doped region is led out as a third electrode and is electrically connected to the second electrode, and the fourth heavily doped region is led out as a fourth electrode;
forming a third well region in the upper surface layer of the second deep well, the third well region having the second conductivity type; forming a floating fifth heavily doped region in the upper surface layer of the third well region, the fifth heavily doped region having the second conductivity type;
forming a fourth well region in the upper surface layer of the third deep well, the fourth well region having the first conductivity type; and forming a sixth heavily doped region in an upper surface layer of the fourth well region, the sixth heavily doped region having the first conductivity type, wherein the sixth heavily doped region is led out and is grounded together with the fourth electrode.
